(19) United States
(12) Patent Application Publication
(10) Pub. No.: US 2006/0087007 A1
(43) Pub. Date: Apr. 27, 2006

(54) Wafer treating apparatus and method

(75) Inventors: Kenichiro Arai, Kyoto (JP); Koji Hasegawa, Kyoto (JP)

Correspondence Address: OSTROLENK FABER GERB & SOFFEN, 1180 AVENUE OF THE AMERICAS, NEW YORK, NY, 100368403, US

(73) Assignee: Dainippon Screen Mfg. Co., Ltd.

(21) Appl. No.: 11/253,988

(22) Filed: Oct. 17, 2005

(30) Foreign Application Priority Data
Oct. 26, 2004 (JP) 2004-310733
Oct. 28, 2004 (JP) 2004-314263

(51) Int. Cl. H01L 23/544

(52) U.S. Cl. 257/620; 438/138

(57) ABSTRACT

A wafer treating apparatus includes a support for supporting a plate-like base, a heating mechanism for heating the base placed on the support, a first coating mechanism for coating a fixing composition on a surface of the base placed on the support, a loading mechanism for loading a wafer on the base coated with the fixing composition, and a second coating mechanism for coating an end surface protective material over an entire circumference at an edge of the wafer bonded to the base.

### BACKGROUND OF THE INVENTION

(1) Field of the Invention

This invention relates to a wafer treating apparatus and method for performing a predetermined treatment of silicon semiconductor, compound semiconductor or other wafers.

(2) Description of the Related Art

In a conventional wafer treating method of the type noted above, wax is applied to and allowed to melt on an upper surface of a base, and a wafer is placed on the base face down, i.e. with the front surface having a circuit and the like formed thereon, facing downward. Then, the wafer is fixed to the base by cooling. The wafer is introduced, along with the base, into a treating tank storing caustic potash (KOH) acting as an etching solution, and is immersed in the etching solution. The back surface of the wafer is thereby chemically ground to a reduced thickness (thinning treatment) (see Japanese Unexamined Patent Publication No. 2003-347254, for example).

The conventional example noted above has the following drawbacks.

The conventional wafer treating method, since it is difficult to render the wax resistant to caustic potash, the wax melts into the etching solution. As a result, the wafer may separate from the base in the course of treatment, or part of the edge of the fixed front surface of the wafer may be etched.

A wafer treating apparatus for carrying out the conventional treating method has a drawback of being ill-suited for prolonged treatment since the base will also be etched. Where, for example, a stainless steel plate is used in place of a silicon wafer, the base will not be etched. However, the stainless steel plate has a thermal expansion coefficient greatly different from that of the wafer, which poses a problem that the wafer separates from the base when heated during treatment.

### SUMMARY OF THE INVENTION

This invention has been made having regard to the state of the art noted above, and its object is to provide a wafer treating apparatus and method capable of avoiding defective treatment due to a wafer separating from a base, which is achieved by covering the edge of the wafer by way of reinforcement with an end surface protective material.

Another object of the invention is to provide a wafer treating apparatus in which a base is formed of an appropriate material to prevent a wafer separating from the base.

The above objects are fulfilled, according to this invention, by a wafer treating apparatus comprising a support for supporting a plate-like base; a heating mechanism for heating the base placed on the support; a first coating mechanism for coating a fixing composition on a surface of the base placed on the support; a loading mechanism for loading a wafer on the base coated with the fixing composition; and a second coating mechanism for coating an end surface protective material over an entire circumference at an edge of the wafer bonded to the base.

According to this invention, the heating mechanism heats the base placed on the support, the first coating mechanism coats a fixing composition on the surface of the base, and then the loading mechanism loads a wafer on the base. The second coating mechanism coats an end surface protective material over an entire circumference at the edge of the wafer bonded to the base by the fixing composition. These features can prevent defective treatment such as the wafer separating from the base.

Preferably, the second coating mechanism is arranged to coat the end surface protective material on the wafer to a position a predetermined width inward from the edge of the wafer.

With the end surface protective material covering the wafer to a position a predetermined width inward from the edge of the wafer, an etching solution, in which the base with the wafer bonded thereto is to be immersed, will have to move an increased distance to reach the end surface of the wafer. Consequently, this measure can reliably avoid inconveniences due to the etching solution spreading to the end surface of the wafer.

In another aspect of the invention, a wafer treating method is provided which comprises a bonding step for placing a wafer on a base, and bonding the wafer to the base with a fixing composition; an end surface protecting step for coating an end surface protective material over an entire circumference at an edge of the wafer bonded to the base; and a thinning step for thinning the wafer by immersing the base with the wafer bonded thereto in an etching solution stored in a treating tank.

According to this invention, the wafer is bonded to the base with the fixing composition, and the edge of the wafer is covered over the entire circumference with the end surface protective material. Subsequently, the wafer thinning step is carried out by immersing the base with the wafer bonded thereto in an etching solution. Since the edge of the wafer bonded to the base is covered by way of reinforcement over the entire circumference by the end surface protective material, the fixing composition is not corroded or melted by the etching solution, which prevents defective treatment such as the wafer separating from the base.

Preferably, the end surface protecting step is executed to coat the end surface protective material on the wafer to a position a predetermined width inward from the edge of the wafer.

With the end surface protective material covering the wafer to a position a predetermined width inward from the edge of the wafer, the etching solution must move an increased distance to reach the end surface of the wafer. This measure can reliably avoid inconveniences due to the etching solution spreading to the end surface of the wafer.

The end surface protective material may include carbon.

Carbon included will render the protective material resistant to an etching solution such as caustic potash.

In a further aspect of the invention, a wafer treating apparatus comprises a support for supporting a plate-like base resistant to an etching solution used in a thinning operation, and having a thermal expansion coefficient similar to that of a wafer; a heating mechanism for heating the base placed on the support; a coating mechanism for coating a fixing composition on a surface of the base placed on the support; and a loading mechanism for loading the wafer on the base coated with the fixing composition.

According to this invention, the heating mechanism heats the base, the coating mechanism coats a fixing composition on the surface of the base, and then the loading mechanism loads a wafer on the base. The base is resistant to an etching solution used in a thinning operation, and has a thermal expansion coefficient similar to that of the wafer. When immersed in a hot etching solution, the wafer and base expand to a similar extent. This prevents the wafer separating from the base.

The base may be formed of SiC or amorphous carbon.

Sic has a thermal expansion coefficient similar to that of a silicon wafer. Amorphous carbon has the next closest value.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a block diagram showing an outline of a wafer bonding apparatus according to the invention;

FIG. 2 is a view in vertical section showing an outline of an etching apparatus according to the invention;

FIG. 3 is a schematic view showing a wafer bonding procedure;

FIG. 4 is a schematic view showing the wafer bonding procedure;

FIG. 5 is a schematic view showing an end surface protection for a bonded wafer;

FIG. 6 is a schematic view showing the end surface protection for the bonded wafer;

FIG. 7 is a view in vertical section showing a state of end surface protection for the wafer;

FIG. 8 is a plan view showing the state of end surface protection for the wafer;

FIG. 9 is a perspective view showing a state during thinning treatment;

FIG. 10 is a view in vertical section showing a state of the wafer after the thinning treatment;

FIG. 11 is a schematic view showing cutting of the wafer;

FIG. 12 is a view in vertical section showing an end surface protection for a wafer in a modified embodiment; and

FIG. 13 is a view in vertical section showing a state of the wafer after thinning treatment in the modified embodiment.

### DESCRIPTION OF THE PREFERRED EMBODIMENTS

A preferred embodiment of this invention will be described in detail hereinafter with reference to the drawings.

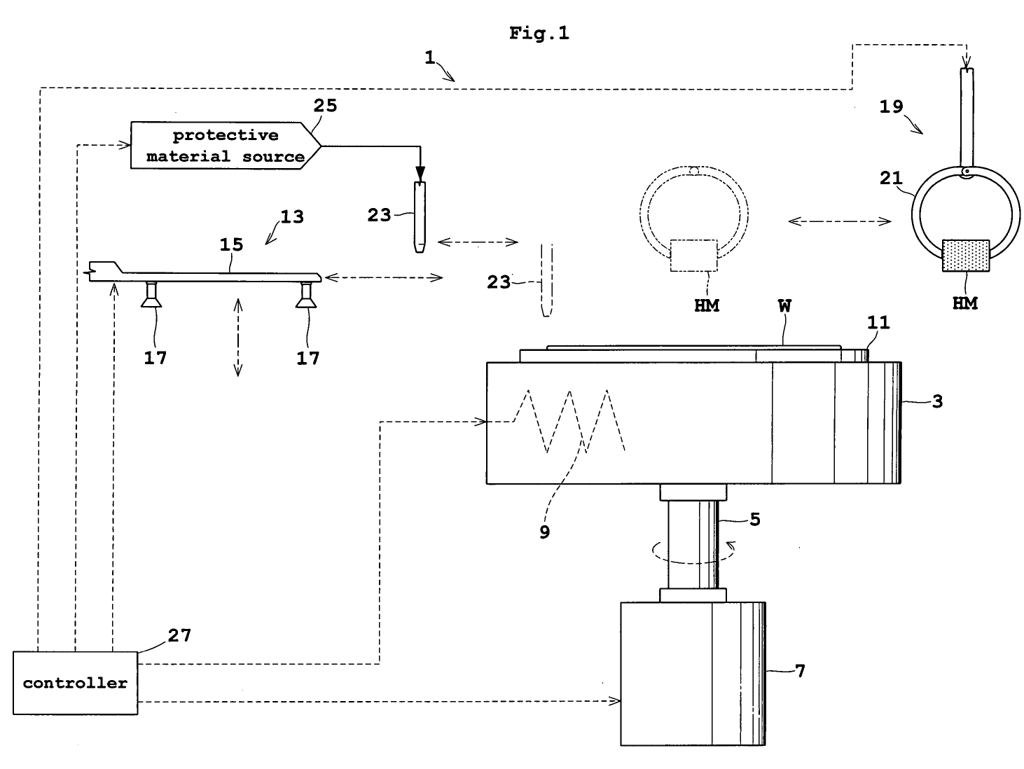

FIG. 1 is a block diagram showing an outline of a wafer bonding apparatus according to the invention.

The wafer bonding apparatus 1 corresponds to the wafer treating apparatus of this invention, and includes a support table 3, a rotary shaft 5 connected to the lower surface of the support table 3, and a motor 7 for rotating the rotary shaft 5. The support table 3 has a built-in heater 9 for heating a plate-like base 11 placed on the upper surface of the table 3. The support table 3 has a slightly larger outside diameter than the base 11. The heater 9 can control temperature to at least the melting point of wax HM described hereinafter. The temperature, although variable with the composition of wax HM, is, for example, about 150 to 170° C. on the surface of the support table 3.

A transport mechanism 13 is disposed laterally (at the left side in FIG. 1) of the support table 3 for transporting bases 11 and wafers W. The transport mechanism 13 includes an arm 15 and a suction device 17. The arm 15 is vertically movable, and extendible and retractable. The suction device 17 can suck the upper surfaces of the base 11 or wafer W.

A wax transport mechanism 19 is disposed also laterally (at the right side in FIG. 1) of the support table 3 for gripping and transporting the wax HM. The wax transport mechanism 19 includes a gripping arm 21 which is vertically movable, and extendible and retractable. The gripping arm 21 grips and transports the wax HM. The wax HM used here may be in a portable form such as solid, solution or film.

Further, a nozzle 23 is disposed laterally (at the left side in FIG. 1) of the support table 3 for supplying an end surface protective material. The nozzle 23 is connected to a protective material source 25 that supplies the end surface protective material. The nozzle 23 is movable between a position sideways from the support table 3 and a position above the edge of wafer W.

The motor 7, heater 9, transport mechanism 13, wax transport mechanism 19 and protective material source 25 are controlled en bloc by a controller 27.

The support table 3 corresponds to the “support” in this invention. The heater 9 corresponds to the “heating mechanism” in the invention. The wax transport mechanism 19 corresponds to the “first coating mechanism” and “coating mechanism”. The transport mechanism 13 corresponds to the “loading mechanism”. The nozzle 23 corresponds to the “second coating mechanism” and the “protective material coating mechanism”. The wax HM corresponds to the “fixing composition” in this invention.

The wax noted above may contain a liquid crystal compound and an organic polymer, for example.

Examples of the “liquid crystal compound” include smectic liquid crystals such as iso-sodium butyrate, sodium oleate, potassium hexahydrobenzoate, sodium stearate, potassium myristate, sodium palmitate, sodium benzoate, ethyl-p-azoxybenzoate, 1-n-dodecyl pyridinium chloride, 1-n-dodecyl pyrinium bromide, 1-n-dodecyl pyridinium iodiodide, and 2-n-tridecyl pyridinium chloride; nematic liquid crystals such as hepta-2,4-diene acid, octa-2,4-diene acid, nona-2,4-diene acid, deca-2,4-diene acid, undeca-2,4-diene acid, and nona-2-en-4-ynoic acid; cholesteric liquid crystals such as cholesterol propionate, cholesterol benzoate, cholesterol palmitate, and cholesterol chloride; and substances showing a complex transition such as p-n-octyl hydroxybenzoic acid, p-n-octyl oxy-m-chlorbenzoic acid, p-n-dodecyl hydroxybenzoic acid, 5-chloro-6-n-heptyl oxy-2-naphthoic acid, and p-trifluoro methoxy phenyl p-(4-pentyl cyclohexyl)phenyl acetylene. It is also possible to use discotic liquid crystals such as compounds having a steroid ester groups in the first, third or fifth place of one benzene ring, and polymer liquid crystal compounds having liquid crystallinity such as aromatic polyester, polyamide and polyimide. These liquid crystal compounds may be used alone or in combination. The liquid crystal compounds, whether used alone or in combination, desirably have a melting point in the range of 35° C. to 200° C., and more desirably in the range of 40° C. to 150° C.

The “organic polymer” desirably has a melting point at least equal to room temperature and below 200° C. Specific examples of such organic polymer include poly (anhydrous azelaic acid), poly [2,6-bis(hydroxymethyl)-4-methyl phenol co-4-hydroxybenzoic acid], poly(1,4-butanediol)bis(4-aminobenzoate), poly(1-butene), poly(1,4-butene adipate-co-1,4-butylene succinate), 6-diisocyanate hexane compound, poly(1,4-butylene adipate)diol, phenol resin, urea resin, melamine resin, unsaturated polyester resin, epoxy resin and polyurethane. These organic polymers may be used alone or in combination, and desirably have a melting point in the range of 35° C. to 200° C., and more desirably in the range of 40° C. to 150° C.

While the wax HM is illustrated as a solid matter in this embodiment, a solution having a solvent mixed therein may also be used in order to facilitate spread over the base 11. Any solvent may be used as long as both the liquid crystal compound and organic polymer included in the composition are dissolvable therein. Examples of solvent include alcohols such as isopropanol, butanol, hexanol, octanol, decanol, undecanol, benzyl alcohol, ethylene glycol, diethylene glycol, propylene glycol, dipropylene glycol and phenol; hydrocarbon solvents such as n-pentane, cyclopentane, n-hexane, cyclohexane, n-heptane, cycloheptan and trimethylbenzene; ketones such as acetone, methyl ethyl ketone, methyl isobutyl ketone, cyclopentanone and cyclohexanone; ethers such as ethyl ether, ethylene glycol dimethyl ether, ethylene glycol diethyl ether, and dioxane; esters such as ethyl acetate, butyl acetate, ethyl butylate, and ethylene glycol monomethyl ether acetate; and polar solvents such as dimethylformamide, dimethylacetamide, N-methyl pyrolidone, and hexamethylphosphomide. These solvents may be used alone or in combination.

The viscosity of wax HM may be adjusted by adding, as appropriate, particulates of a metal oxide such as aluminum oxide, zirconium oxide, titanium oxide or silicon oxide.

The end surface protective material stored in the protective material source 25 is resistant to the etching solution described hereinafter, and desirably in a liquid or gel form having a relatively high viscosity in time of application, and low fluidity. The above features are desirable because, when supplied to the edge of wafer W, such protective material has little possibility of flowing away to surrounding areas. Specifically, the end surface protective material may, for example, be a polymeric material such as polyethylene or paraffin acting as the base and containing carbon, or an organic resist. A solvent may be mixed into the protective material to improve application properties and to dry in a short time.

The base 11 noted above, desirably, is SiC or amorphous carbon (or glassic carbon) where the wafer W is a silicon wafer. Particularly, SiC is preferred since it has resistance to KOH, and has a thermal expansion coefficient similar to that of silicon wafers as shown hereunder. Thermal expansion coefficients of various materials are shown below by way of example.

silicon wafer=3.9×10⁻⁶/K

SiC=4.3×10⁻⁶/K

amorphous carbon=3.0×10⁻⁶/K (for comparison)

SUS 304=17.3×10⁻⁶/K

Ti=8.9×10⁻⁶/K

The etching solution of KOH is used in the etching apparatus 29 described hereinafter, after being heated to a high temperature of about 70° C., for example. The wafer W and base 11 immersed in the etching solution will undergo a temperature change from room temperature (23° C.) to 70° C. When the base 11 expands greatly relative to the wafer W, the adhesion by the wax HM lowers, resulting in the wafer W separating or displacing from the base 11, thereby causing defective treatment. Where, for example, the length of the materials is 100 mm and temperature change ΔT is 47° C., elongations of the respective materials are as follows.:

silicon wafer: 100 mm×47° C.×3.9×10⁻⁶=0.01833 mm

SiC: 100 mm×47° C.4.3×10⁻⁶=0.02021 mm

amorphous carbon: 100 mm×47° C.×3.0×10⁻⁶=0.0141 mm

SUS 304: 100 mm×47° C.×17.3×10⁻⁶=0.08131 mm

Ti: 100 mm×47° C.×8.9×10⁻⁶=0.04183 mm

With reference to the elongation of the silicon wafer, the rates of elongation of the other materials are as follows:

SiC: 1.102

amorphous carbon: 0.769

SUS 304: 4.435

Ti: 2.282

These results show that SiC is the most desirable as the base 11, and amorphous carbon is next.

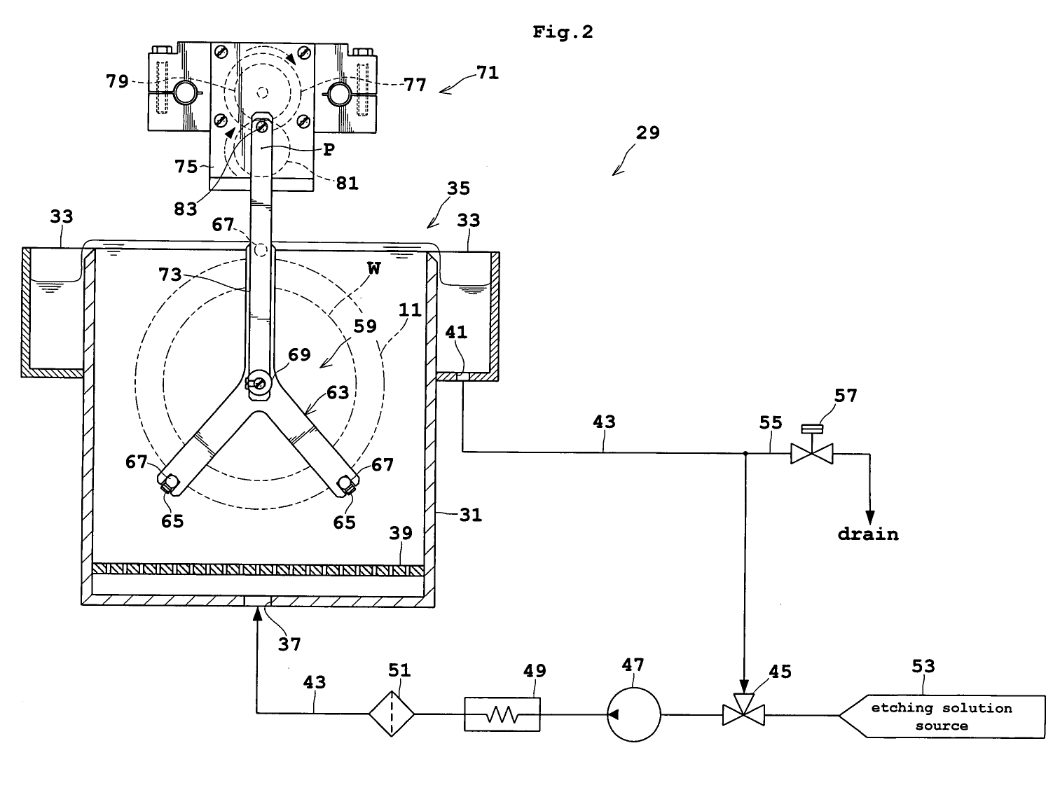

Next, the etching apparatus will be described with reference to FIG. 2. FIG. 2 is a view in vertical section showing an outline of the etching apparatus according to the invention.

The etching apparatus 29 is constructed for performing thinning treatment of wafers W by chemically etching the wafers W bonded to the bases 11 to a predetermined thickness. The apparatus 29 includes an inner tank 31 for storing the etching solution, and an outer tank 33 for collecting the etching solution overflowing the inner tank 31. The inner tank 31 and outer tank 33 constitute a treating tank 35. The inner tank 31 has a feed port 37 formed in the bottom thereof for introducing the etching solution, and a flow straightener 39 disposed above the feed port 27. The flow straightener 39 defines a plurality of fine bores over the entire area thereof for straightening flows of the etching solution introduced from the feed port 37 and guiding the flows into the inner tank 31.

The outer tank 33 has a drain port 41 formed in one position thereof. Circulation piping 43 is connected to the drain port 41 and the feed port 37 noted above. The circulation piping 43 has a three-way valve 45, a pump 47, an in-line heater 49 and a filter 51 arranged in the stated order thereon from upstream to downstream. An etching solution source 53 is connected to the three-way valve 45. A branch pipe 55 is connected to the circulation piping 43 between the drain port 41 and three-way valve 45. The branch pipe 55 has a switch valve 57 mounted thereon, which is operable to drain the etching solution from the outer tank 33 through the circulation piping 43 and branch pipe 55. The in-line heater 49 heats caustic potash (KOH) acting as the etching solution to a predetermined temperature.

A holding mechanism 59 includes a pair of holding frames 63 presenting a shape of inverted Y as seen from the front side of wafers W, a mounting recess 65 formed in each distal end of the holding frames 63, two engaging members 67 fixedly attached to the two lower mounting recesses 65 of each holding frame 63, an engaging member 67 detachably attached to the one upper mounting recess 65 of each holding frame 64. Each engaging member 67 defines a plurality of grooves, not shown, for engaging the edges of the bases 11. Each engaging member 67 has opposite ends thereof attached to the front and rear holding frames 33. The engaging members 67 stably support the bases 11 having the wafers W attached thereto, by engaging three peripheral positions of each base 11.

The front and rear holding frames 63 have pins 69 fixed to and projecting outward from central positions thereof. The pins 69 are connected to connecting pieces 73 suspended from a drive mechanism 71 disposed above the treating tank 35. The connecting pieces 73 have lower ends thereof fixedly screwed to the pins 69, so that the connecting pieces 73 are fixed relative to the holding frames 63.

The drive mechanism 71 has a function for revolving the holding mechanism 59 in the inner tank 31, about a horizontal axis extending along a direction of arrangement of the bases 11 and wafers W. Specifically, the drive mechanism 71 includes a frame 75, a motor 77 attached in the frame 75, a gear 79 of the motor 77, and a gear 81 engaged with a lower part of the gear 79. The connecting pieces 73 are rotatably attached by screws 83 to the gear 81 in positions offset from its axis of rotation P. The drive mechanism 71 is vertically movable between a standby position and a treating position by a lift mechanism not shown.

When a rotary shaft of the motor 77 noted above is driven clockwise in FIG. 2, the upper ends of the connecting pieces 73 are revolved, through the gears 79 and 81, around the axis of rotation P while the connecting pieces 73 are maintained in vertical posture. As a result, the holding mechanism 59 fixed to the lower ends of the connecting pieces 73 makes a revolving motion in the inner tank 31.

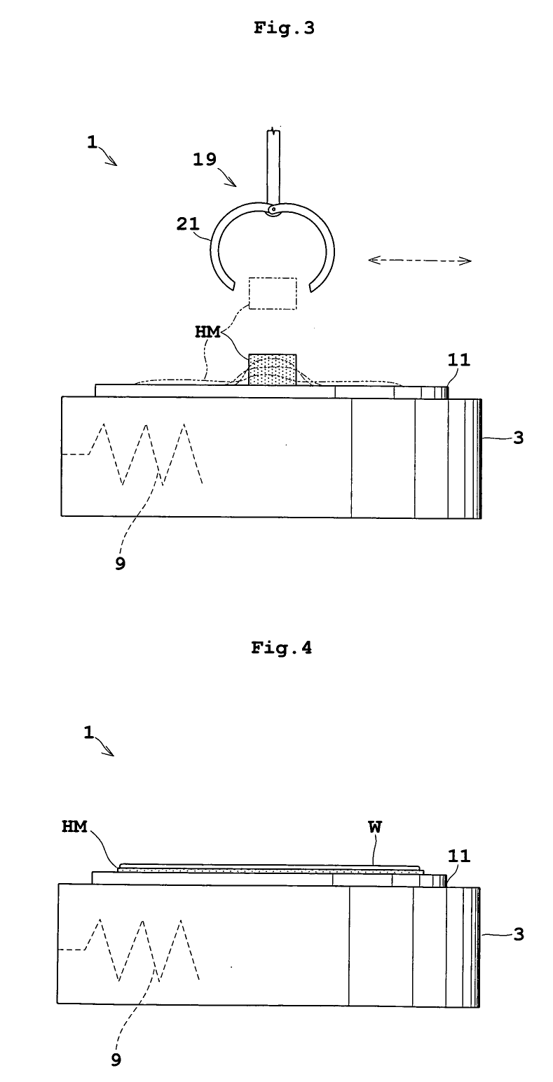

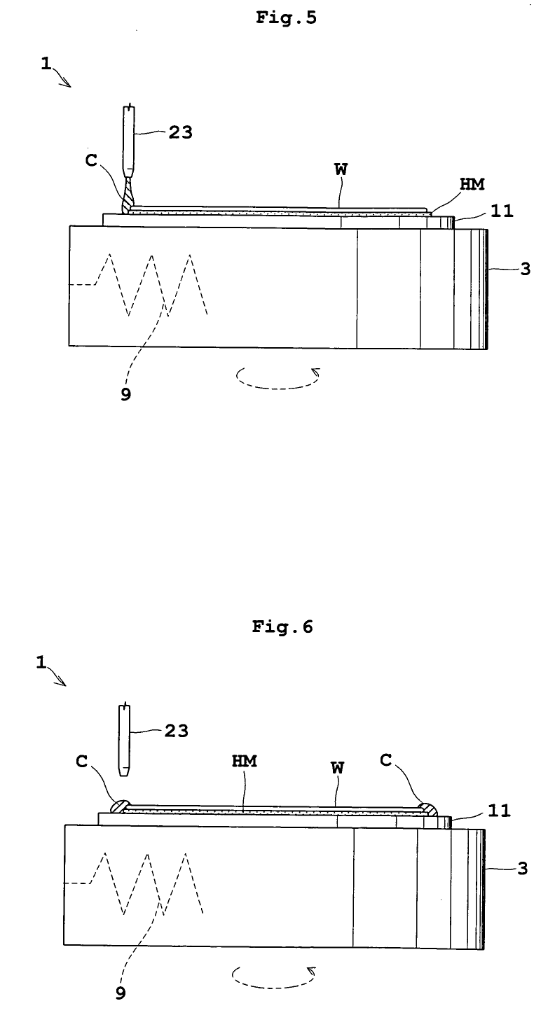

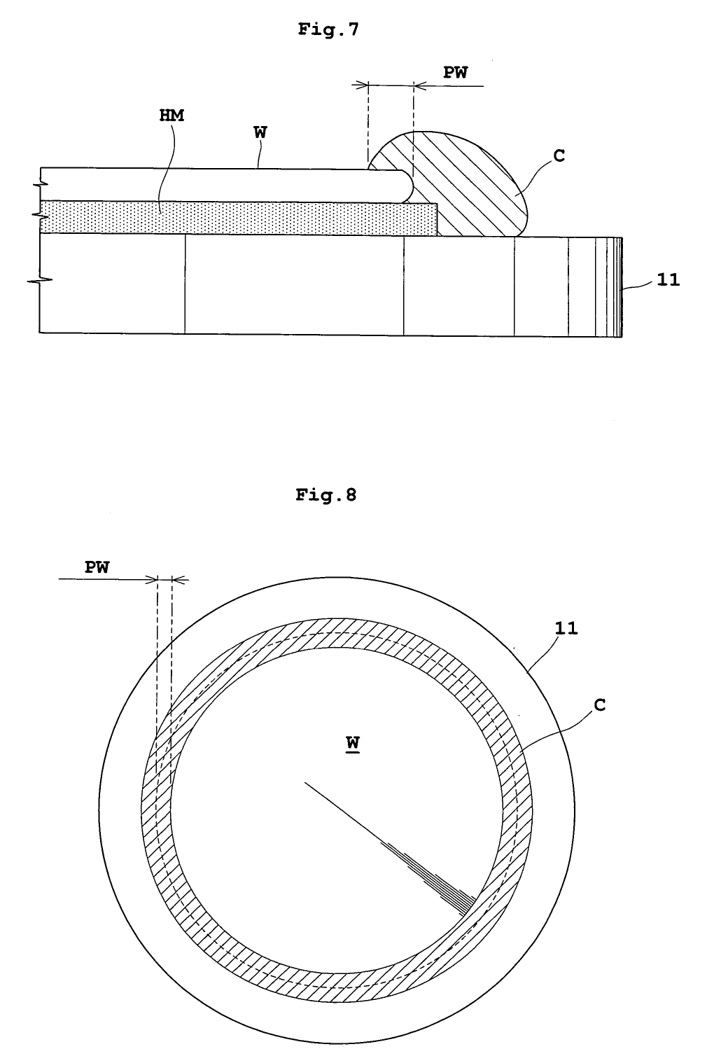

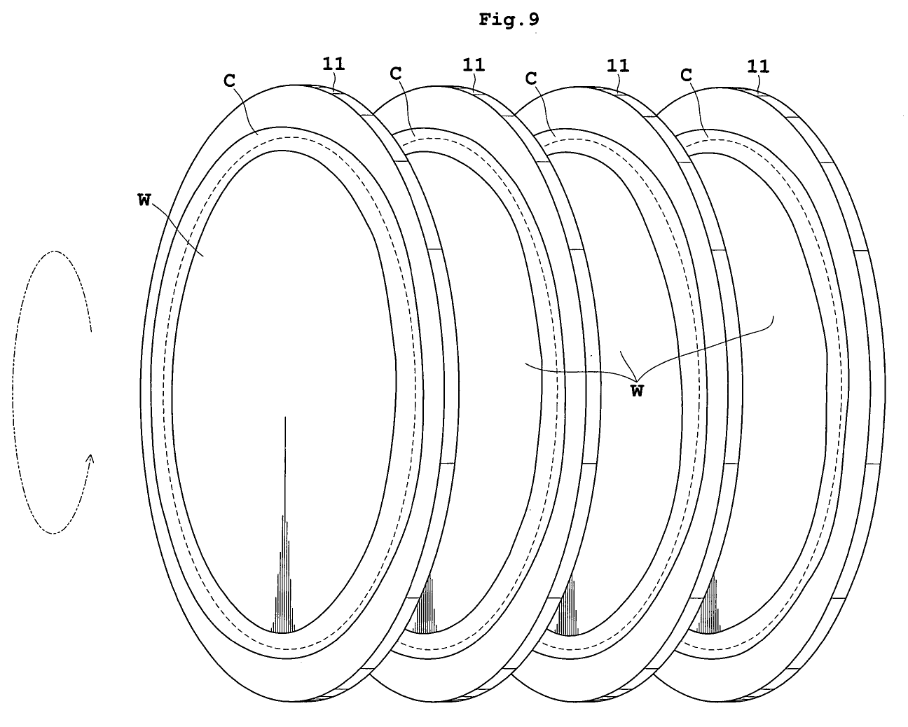

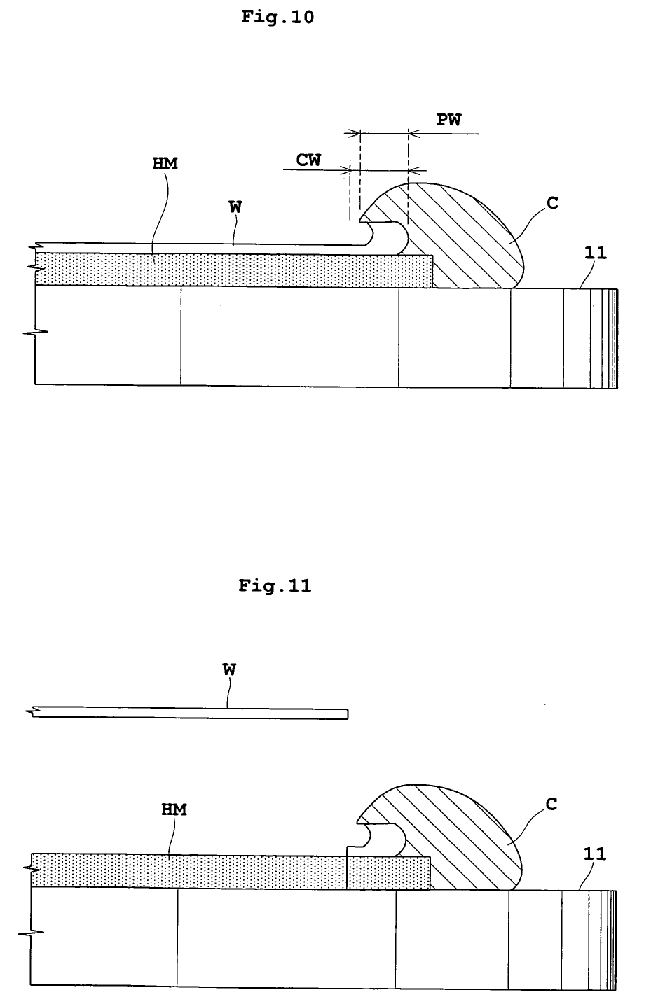

Next, a specific example of treatment will be described with reference to FIGS. 3 through 10. FIGS. 3 and 4 are schematic views showing a procedure of bonding a wafer to a base. FIGS. 5 and 6 are schematic views showing an end surface protection provided in time of wafer bonding. FIG. 7 is a view in vertical section showing a state of end surface protection of the wafer. FIG. 8 is a plan view showing the state of end surface protection of the wafer. FIG. 9 is a perspective view showing a state during thinning treatment. FIG. 10 is a view in vertical section showing a state of the wafer after the thinning treatment.

First, a base 11 is placed on the support table 3, and is heated to a predetermined temperature (e.g. 168° C.) by the heater 9. The wax transport mechanism 19 places the wax HM with a melting point of 148° C., for example, on a central part of the base 11 (FIG. 3). Then, the wax HM melts and covers the entire upper surface of the base 11. At this time, the motor 7 may be driven to rotate the support table 3 in order to speed up the spread of wax HM.

Next, the transport mechanism 13 carries in a wafer W, and places it on the upper surface of the base 11 (FIG. 4). The wafer W in this state has a circuit and the like formed on the lower surface thereof, the upper surface being its back surface. After placing the wafer W, the heating by the heater 9 is stopped. When temperature falls well below the melting point of wax HM, the wafer W is bonded and fixed to the base 11 (bonding step). As the heating by the heater 9 is stopped, a cooling mechanism, not shown, may be operated to shorten the time taken for the fixation.

After the wax HM hardens to fix the wafer W to the base 11, the nozzle 23 is moved above an end surface of the wafer W as shown in FIG. 5. Then, the end surface protective material C is delivered from the nozzle 23 while the motor 7 is driven to rotate the support table 3 at low speed. The drive by the motor 7 is stopped when the support table 3 has made one rotation. Then, as shown in FIGS. 6 through 8, the edge of wafer W is covered by the end surface protective material C over the entire circumference. The end surface protective material C covers also the wax HM exposed from between the lower surface of wafer W and the upper surface of base 11 (end surface protecting step).

As shown in FIGS. 7 and 8, the above end surface protection desirably is applied over a predetermined width PW inward from the edge (end surface) of wafer W. With the end surface protective material C covering the wafer W to a rather large extent inward from the edge thereof, the etching solution must move an increased distance to reach the end surface of wafer W in time of the thinning treatment described hereinafter. This measure can reliably avoid inconveniences due to the etching solution spreading to the end surface of wafer W.

When or after the edge of wafer W is covered by the end surface protective material C, the heater 9 may be operated to heat the wafer W and protective material C to a predetermined temperature, thereby to shorten the curing time of the end surface protective material C. However, this temperature should be well below the melting point of wax HM so that the wax HM having settled will not melt again.

After the end surface protective material C hardens, the transport mechanism 13 removes the base 11 with the wafer W adhering thereto from the support table 3, and a new set of base 11 and wafer W is processed as described above. When a predetermined number of wafers W have been bonded to the bases 11, the thinning treatment is performed next.

The bases 11 with the wafers W adhering thereto are transported to the etching apparatus 29. As shown in FIG. 2, the bases 11 held by the holding mechanism 59 are moved into the inner tank 31 storing the etching solution heated to a predetermined temperature (e.g. 70° C.), whereby the wafers W are immersed in the etching solution. Then, the motor 77 is driven for a predetermined time (e.g. 30 minutes) to revolve the wafers W in the etching solution as shown in FIG. 9. As a result, the thickness of wafers W six inches in diameter is reduced to 50cm or less, for example. FIG. 10 schematically shows a vertical section resulting from the thinning treatment. Although the thickness of each wafer W is reduced as illustrated, the edge of wafer W covered by the end surface protective material C substantially retains the original thickness without being etched.

Although the wafers W are immersed, along with the bases 11, in the hot etching solution for a long time, the edges of the wafers W bonded to the bases 11 by the wax HM are covered by way of reinforcement over the entire circumference by the end surface protective material C. Consequently, the wax HM is not corroded or melted by the etching solution, which prevents defective treatment such as the wafers W separating from the bases 11.

Since the bases 11 are formed of a material having a thermal expansion coefficient similar to that of the wafers W, the bases 11 do not expand to a large extent relative to the wafers W. This prevents lowering of the adhesion by the wax HM, thereby preventing separation or displacement of the wafers W from the bases 11, and thus preventing defective treatment.

Upon lapse of a predetermined thinning time, the drive mechanism 71 is operated to remove the bases 11 with the wafers W adhering thereto from the inner tank 31. Then, as shown in FIG. 10, each wafer W is cut at a cutting width CW slightly inward of the predetermined width PW of the end surface protective material C (cutting step). This cutting step is executed by using a high-output laser beam, for example. Consequently, as shown in FIG. 11, a wafer W is cut with a slightly smaller diameter than the original, and with a reduced thickness.

Each wafer W may be separated from the base 11 through a dissolving step for immersing the wafer W and base 11 in a solution that dissolves the end surface protective material C, instead of carrying out the above cutting operation. Each wafer W may be stripped off the base 11 by ashing.

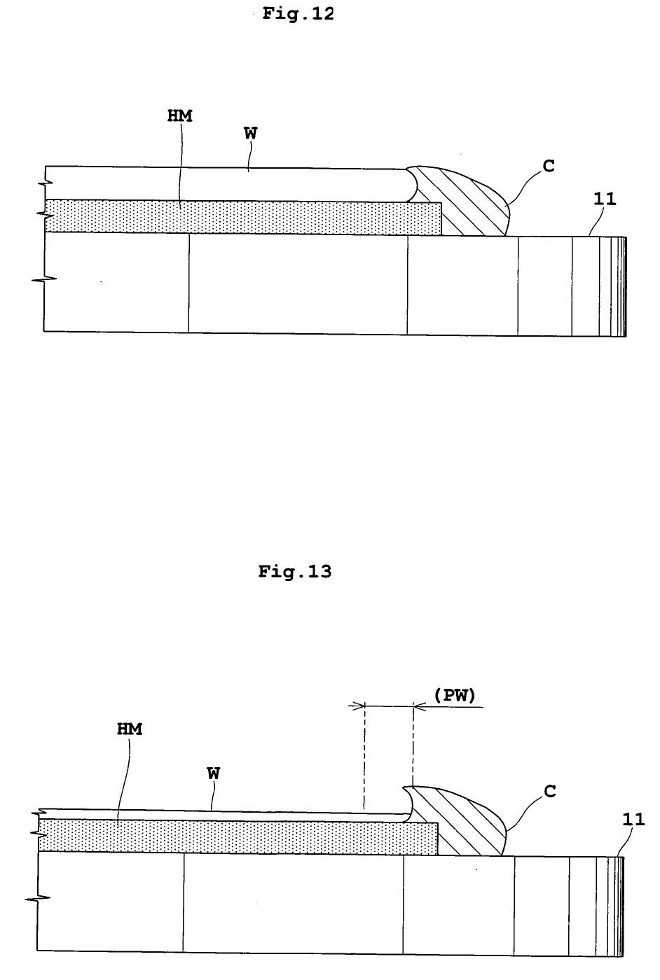

In the embodiment described above, the end surface protective material C covers the upper surface of wafer W the predetermined width PW inward from the edge of wafer W. As shown in FIG. 12, the end surface protective material C may cover only the edge (end surface) of wafer W along with the wax HM. Then, as shown in FIG. 13, the portion of the predetermined width PW from the edge of wafer W may be used effectively in subsequent steps. This can cut down the cost of the end surface protective material C also.

This invention is not limited to the above embodiment, but may be modified as follows:

(1) For example, the end surface protective material may be shaped annular beforehand according to the outside diameter of wafer W, and fitted on the edge of wafer W. This modification assures the same functions and effects as the foregoing embodiment in which the end surface protection material C is directly applied from the nozzle 23 corresponding to the second coating mechanism and protective material coating mechanism, and can shorten the time required for providing the end surface protection.

(2) In the described construction, the support table 3 is rotated to apply the end surface protective material C to the entire circumference of wafer W. Instead of moving the support table 3, the nozzle 23 may be moved according to the shape of wafer W to apply the protective material C.

(3) In the foregoing embodiment, the thinning treatment is the batch type. Instead, the single-wafer type may be employed for treating one wafer W at a time.

(4) As the heating mechanism, the heater 9 mounted in the support table 3 may be replaced by a heating mechanism for emitting light from above the support table 3.

This invention may be embodied in other specific forms without departing from the spirit or essential attributes thereof and, accordingly, reference should be made to the appended claims, rather than to the foregoing specification, as indicating the scope of the invention.

What is claimed is:

1. A wafer treating apparatus comprising:
a support for supporting a plate-like base;
a heating mechanism for heating the base placed on said support;
a first coating mechanism for coating a fixing composition on a surface of the base placed on said support;
a loading mechanism for loading a wafer on the base coated with the fixing composition; and
a second coating mechanism for coating an end surface protective material over an entire circumference at an edge of the wafer bonded to said base.

2. An apparatus as defined in claim 1, wherein said second coating mechanism is arranged to coat the end surface protective material on the wafer to a position a predetermined width inward from the edge of the wafer.

3. An apparatus as defined in claim 1, wherein said support is arranged to support said base resistant to an etching solution used in a thinning operation, and having a thermal expansion coefficient similar to that of the wafer.

4. An apparatus as defined in claim 2, wherein said support is arranged to support said base resistant to an etching solution used in a thinning operation, and having a thermal expansion coefficient similar to that of the wafer.

5. An apparatus as defined in claim 1, wherein said base is formed of SiC.

6. An apparatus as defined in claim 1, wherein said base is formed of amorphous carbon.

7. A wafer treating method comprising:
a bonding step for placing a wafer on a base, and bonding the wafer to the base with a fixing composition;
an end surface protecting step for coating an end surface protective material over an entire circumference at an edge of the wafer bonded to said base; and
a thinning step for thinning the wafer by immersing the base with the wafer bonded thereto in an etching solution stored in a treating tank.

8. A method as defined in claim 7, wherein said end surface protecting step is executed to coat the end surface protective material on the wafer to a position a predetermined width inward from the edge of the wafer.

9. A method as defined in claim 7, further comprising a cutting step, following said thinning step, for cutting the wafer in a position inward of a predetermined width from the edge of the wafer.

10. A method as defined in claim 7, further comprising a dissolving step, following said thinning step, for dissolving and removing said end surface protective material with a solution.

11. A method as defined in claim 8, further comprising a dissolving step, following said thinning step, for dissolving and removing said end surface protective material with a solution.

12. A method as defined in claim 7, wherein said end surface protective material includes carbon.

13. A method as defined in claim 8, wherein said end surface protective material includes carbon.

14. A method as defined in claim 9, wherein said end surface protective material includes carbon.

15. A wafer treating apparatus comprising:
a support for supporting a plate-like base resistant to an etching solution used in a thinning operation, and having a thermal expansion coefficient similar to that of a wafer;
a heating mechanism for heating the base placed on said support;
a coating mechanism for coating a fixing composition on a surface of the base placed on said support; and
a loading mechanism for loading the wafer on the base coated with the fixing composition.

16. An apparatus as defined in claim 15, wherein said base is formed of SiC.

17. An apparatus as defined in claim 15, wherein said base is formed of amorphous carbon.

18. An apparatus as defined in claim 15, further comprising a protective material coating mechanism for coating an end surface protective material over an entire circumference at an edge of the wafer bonded to said base.

19. An apparatus as defined in claim 16, further comprising a protective material coating mechanism for coating an end surface protective material over an entire circumference at an edge of the wafer bonded to said base.

20. An apparatus as defined in claim 17, further comprising a protective material coating mechanism for coating an end surface protective material over an entire circumference at an edge of the wafer bonded to said base.
